(19) United States
(12) Patent Application Publication
(10) Pub. No.: US 2022/0195245 A1
(43) Pub. Date: Jun. 23, 2022

(54) Selective Chemical Mechanical Planarization Polishing

(71) Applicant: Versum Materials US, LLC, Tempe, AZ (US)

(72) Inventors: Xiaobo Shi, Chandler, AZ (US); Chia-Chien Lee, Hsinchu (TW); Mark Leonard O'Neill, Queen Creek, AZ (US)

(73) Assignee: Versum Materials US, LLC, Tempe, AZ (US)

(21) Appl. No.: 17/600,895

(22) PCT Filed: Apr. 16, 2020
(86) PCT No.: PCT/US2020/028463

§ 371 Date: Oct. 1, 2021

Related U.S. Application Data
(60) Provisional application No. 62/840,338, filed on Apr. 29, 2019.

(51) Int. Cl. C09G 1/02; H01L 21/304

(52) U.S. Cl. CPC C09G 1/02; H01L 21/304

(57) ABSTRACT

Chemical Mechanical Planarization (CMP) polishing compositions, methods and systems are used to polish low-k or ultra-low-k films with reasonable high removal rates while to polish oxide and nitride films with relative low removal rates. The compositions use 5 abrasive, chemical additives to boost low-k or ultra-low-k film removal rates and suppress oxide and nitride film removal rates for achieving high selectivity, such as low-: TEOS, ultra-low-K: TEOS, and low-k: SiN or ultra-low-k: SiN.

### BACKGROUND OF THE INVENTION

This invention relates to chemical mechanical planarization (CMP) for low-k or ultra-low-K film CMP chemical polishing compositions, system and process.

More specifically, the invention relates to selective CMP polishing of low-k or ultra-low-K film over oxide and/or nitride layer.

In the fabrication of microelectronics devices, an important step involved is polishing, especially surfaces for chemical-mechanical polishing for recovering a selected material and/or planarizing the structure.

In more advanced node CMP process, for example, a low-k or ultra-low-K layer is deposited over a SiO₂ layer or a SiN layer to serve as a capping layer. Therefore, an important step in CMP is to remove such low-k film capping layer and stop on oxide or SiN layer. Therefore, it is important invent CMP polishing compositions which can quickly remove low-k or ultra-low-K film capping layer and have high selectivity of polishing low-k films vs oxide or SiN films.

U.S. Pat. No. 6,569,349 discloses a method and composition for planarizing a substrate. The composition includes one or more chelating agents, one or more oxidizers, one or more corrosion inhibitors, a polar solvent, and deionized water. The composition may further comprise one or more surfactants, one or more agents to adjust the pH and/or abrasive particles. The method comprises planarizing a substrate using a composition including a polar solvent.

J. Electrochem. Soc., Vol. 146, Issue 11, pp. 4309-4315 (1999) reported CMP of bis-benzocyclobutene™ (BCB) and “silicon-application—” (SiLK™) polymers in slurries commonly used for copper removal is studied.

Chemical Mechanical Planarization (CMP) polishing compositions, methods and systems are used to polish low-k or ultra-low-k films with reasonable high removal rates while to polish oxide and nitride films with relative low removal rates. The compositions use abrasive, chemical additives to boost low-k or ultra-low-k film removal rates and suppress oxide and nitride film removal rates for achieving high selectivity, such as low-K: tetraethyl orthosilicate (TEOS), ultra-low-K: TEOS, and low-k: SiN or ultra-low-k: SiN.

US Patent Application 20090045164 disclosed “Universal Barrier CMP Slurry for Use with Low Dielectric Constant Interlayer Dielectrics”. It teaches that in the second phase of the barrier-CMP method, when the polishing interface is close to the low-k dielectric material, the polishing conditions are changed so as to be highly selective, producing a negligible removal rate of the low-k dielectric material. The polishing conditions can be changed in a number of ways, including changing parameters of the composition of the barrier slurry composition, and mixing an additive into the barrier slurry.

U.S. Pat. No. 6,270,395 disclosed “Oxidizing polishing slurries for low dielectric constant materials”. The slurry is formed utilizing non-oxidizing particles with a separate oxidizing agent, oxidizing particles alone or reducible abrasive particles with a compatible oxidizing agent. The particles can be formed of a metal oxide, nitride, or carbide material, by itself or mixtures thereof, or can be coated on a core material such as silicon dioxide or can be coformed therewith. A preferred oxidizing slurry is multi-modal in particle size distribution. Although developed for utilization in CMP semiconductor processing the oxidizing slurry of the present invention also can be utilized for other high precision polishing processes

US Patent Application 20030139069 disclosed a chemical mechanical planarizing method for removing silicon carbide hardmask capping materials in the presence of Low-k dielectrics contained on semiconductor wafers. The method uses zirconia-containing slurries at acidic pH levels with the abrasive having a positive zeta potential to facilitate silicon carbide removal.

U.S. Pat. No. 6,046,112 disclosed a chemical mechanical polishing slurry comprising ZrO₂ particles and a surfactant, TMAH (Tetra-Methyl-Ammonium Hydroxide) or TBAH (Tetra-Butyl-Ammonium Hydroxide) in a water solution. The slurry is suitable for polishing low dielectric constant k siloxane based SOG layers at a high polish removal rate and with high selectivity over deposited silicon oxide layers. Polish removal rates of up to 4000 Angstroms/min. are achieved at a selectivity ratio as high as 8.

U.S. Pat. No. 6,974,777 disclosed a CMP compositions and method of polishing a substrate containing a low-k dielectric layer comprising (i) contacting the substrate with a chemical-mechanical polishing system comprising (a) an abrasive, a polishing pad, or a combination thereof, (b) an amphiphilic nonionic surfactant, and (c) a liquid carrier, and (ii) abrading at least a portion of the substrate to polish the substrate.

However, those prior disclosed low-k or ultra-low-k film polishing compositions did not fully address the importance of low-k or ultra-low-k film vs oxide or SiN film selectivity and did not address low-k film removal rate boosting and SiN removal rate suppressing.

Therefore, it should be readily apparent from the foregoing that there remains a need within the art for compositions, methods and systems of low-k or ultra-low-k film chemical mechanical polishing that can afford the suppressed SiN film and oxide film removal rates and the increased low-k or ultra-low-k film removal rates in a low-k or ultra-low-k chemical and mechanical polishing (CMP) process.

### SUMMARY OF THE INVENTION

The present invention provides low-K or ultra-low-K film CMP polishing compositions for high low-K dielectric film removal rates and for high selectivity of low-K film vs oxide or low-K film vs nitride.

The present invented low-K dielectric film CMP polishing compositions offer a unique combination of using high purity colloidal silica abrasives and chemical additives as SiO₂ film and SiN film removal rate suppressing agents at wide pH range including acidic, neutral and alkaline pH conditions.

In one aspect, there is provided a low-K or ultra-low-K film CMP polishing composition comprises:

abrasive selected from the group consisting of inorganic oxide particles, coated inorganic oxide particles, and combinations thereof; chemical additive selected from the group consisting of a low-K or ultra-low-K film removal rate boosting agent, an oxide or nitride film removal rate suppressing agent, and combinations thereof;
water soluble solvent; and
optionally
surface wetting agent; and
pH adjuster;
wherein the composition has a pH of 2 to 13, preferably 4 to 13, and more preferably 11 to 13.

The inorganic oxide particles include but are not limited to calcined ceria, colloidal silica, high purity colloidal silica, alumina, titania, zirconia particles.

The suitable abrasives used in the polishing compositors included, but not limited to, fumed silica particles, colloidal silica particles or high purity colloidal silica particles with various sizes and shapes.

The coated inorganic oxide particles include but are not limited to the ceria-coated inorganic oxide particles include, such as, ceria-coated colloidal silica, ceria-coated high purity colloidal silica, ceria-coated alumina, ceria-coated titania, ceria-coated zirconia, or any other ceria-coated inorganic oxide particles.

The water soluble solvent includes but is not limited to deionized (Dl) water, distilled water, and alcoholic organic solvents.

The first type of chemical additive functions as low-K or ultra-low-K film removal rate boosting agent. The first type of chemical additive has an organic aromatic ring with sulfonate or sulfonic acid functional groups directly connected to the organic aromatic ring or linked to the aromatic ring through alkyl linkage groups for boosting low-K or ultra-low-K film removal rate.

First type of chemical additives is selected from the group comprising of below:

(a)

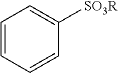

where —R can be hydrogen atom, a metal ion, or ammonium ion;

(b)

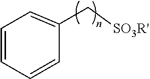

where —R′ can be hydrogen atom, a metal ion or ammonium ion; n can be ranged from 1 to 12 which represents the various length of alkyl linkage group —CH₂—; and the metal ion is sodium ion, or potassium ion; and (c)combinations thereof.

When R is hydrogen atom, the chemical additive is benzenesulfonic acid.

When —R is a metal ion such as sodium ion, potassium ion; or ammonium ion, the chemical additive is a salt of benzenesulfonate.

The second type of chemical additives functions as an oxide or a nitride film removal rate suppressing agent. The second type of chemical additives are inorganic salts of aluminate, include but are not limited to sodium salt, potassium salt or ammonium salt.

In another aspect, there is provided a method of chemical mechanical polishing (CMP) a substrate having at least one surface comprising low-k or ultra-low-K film using the chemical mechanical polishing (CMP) composition described above in low-K film CMP process.

In another aspect, there is provided a system of chemical mechanical polishing (CMP) a substrate having at least one surface comprising low-K or ultra-low-K using the chemical mechanical polishing (CMP) composition described above in low-K dielectric film CMP process.

The polished low-k or ultra-low-k films included, but not limited to, fluorine doped silicon oxide, carbon-doped oxide, porous silicon oxide, spin-on organic polymeric dielectrics, and spin-on silicon based polymeric dielectric film, etc.

The polished oxide films can be Chemical vapor deposition (CVD), Plasma Enhance CVD (PECVD), High Density Deposition CVD(HDP), or spin on oxide films.

The polished nitride films can be Chemical vapor deposition (CVD) SiN, Plasma

Enhance CVD (PECVD) SiN, or LPCVD SiN film.

### BRIEF DESCRIPTION OF SEVERAL VIEWS OF THE DRAWINGS

FIG. 1. Ultra-low-k film with k-constant at 2.5 (LK2.5) and TEOS Film Removal Rate (RR) (A/min.) & LK2.5 Film: TEOS Selectivity

FIG. 2. LK2.5 and SiN Film RR (A/min.) & LK2.5 Film: SiN Selectivity

FIG. 3. Effects of pH on LK2.5 & TEOS RR(A/min.) & Selectivity of LK2.5: TEOS

FIG. 4. Effects of pH on LK2.5 and SiN RR(A/min.) & Selectivity of LK2.5: SiN

### DETAILED DESCRIPTION OF THE INVENTION

This invention relates to the low-k or ultra-low-K film CMP chemical polishing compositions and chemical mechanical planarization (CMP) for low-K or ultra-low-K film

CMP process.

In the fabrication of microelectronics devices, an important step involved is polishing, especially surfaces for chemical-mechanical polishing for recovering a selected material and/or planarizing the structure.

In more advanced node CMP process, for example, a low-k or ultra-low-K layer is deposited over a SiO₂ layer or a SiN layer to serve as a capping layer. Therefore, an important step in CMP is to remove such low-k film capping layer and stop on oxide or SiN layer. Therefore, it is important invent CMP polishing compositions which can quickly remove low-k or ultra-low-K film capping layer and have high selectivity of polishing low-k films vs oxide or SiN films.

More specifically, the disclosed chemical mechanical polishing (CMP) composition for polishing low-K or ultra-low-K film CMP applications have a unique combination of using high purity colloidal silica abrasive particles with different sizes and shaped and the suitable chemical additives as low-film removal rate boosting agents, and oxide or nitride film removal rate suppressing agents.

The suitable chemical additives include but are not limited to two types of chemical additives.

The first type of chemical additive functions as low-K or ultra-low-K film removal rate boosting agent. The first type of chemical additive has an organic aromatic ring with sulfonate or sulfonic acid functional groups directly connected to the organic aromatic ring or linked to the aromatic ring through alkyl linkage groups for boosting

First type of chemical additives has one of the general molecular structures shown below:

(a)

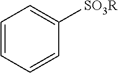

where —R can be hydrogen atom, a metal ion, or ammonium ion;

(b)

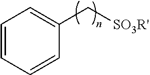

where —R′ can be hydrogen atom, a metal ion, or ammonium ion; n can be ranged from 1 to 12 which represents the various length of alkyl linkage group —CH₂—; and the metal ion is sodium ion, or potassium ion.

When R is hydrogen atom in (a), the chemical additive is benzenesulfonic acid.

When —R in (a) is a metal ion such as sodium ion, potassium ion, or ammonium ion, the chemical additive is a salt of benzenesulfonate.

The second type of chemical additives functions as an oxide or a nitride film removal rate suppressing agent. The second type of chemical additives are inorganic salts of aluminate, include but are not limited to sodium salt, potassium salt or ammonium salt.

The two types of chemical additives are both used in the low-k or ultra-low-k film CMP polishing compositions to provide the benefits of achieving high low-k film removal rates, low oxide and SiN film removal rates, high and tunable low-k: Oxide or low-k: SiN selectivity.

The low-k or ultra-low-k CMP polishing composition contains 0.0001 wt. % to 2.0% wt. %, preferably 0.001 wt. % to 1.5 wt. %, and preferable 0.0025 wt. % to 1.0 wt. % first type of chemical additives as low-k or ultra-low-k film removal rate boosting agents.

The low-k or ultra-low-k CMP polishing composition contains 0.001 wt. % to 2.0% wt. %, preferably 0.0025 wt. % to 1.0 wt. %, and preferable 0.05 wt. % to 0.75 wt. % second type of chemical additives as oxide film and SiN film removal rate suppressing agents.

In one aspect, there is provided a low-k or ultra-low-k film CMP polishing composition comprises:
abrasives;
first type of chemical additives has one of the general molecular structures shown below:

(a)

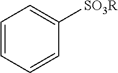

where —R can be hydrogen atom, a metal ion, or ammonium ion;

(b)

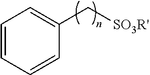

where —R′ can be hydrogen atom, a metal ion, or ammonium ion; n can be ranged from 1 to 12 which represents the various length of alkyl linkage group -CH₂-; and the metal ion is sodium ion, or potassium ion.
second type of chemical additive selected from the group consisting of inorganic salts of aluminate;
a water-soluble solvent; and
optionally
biocide; and
pH adjuster;
wherein the composition has a pH of 2 to 13, preferably 4 to 13, and more preferably 11 to 13.

When R is hydrogen atom, the first type of the chemical additive is benzenesulfonic acid.

When —R is a metal ion such as sodium ion, potassium ion, or ammonium ion, the first type of the chemical additive is a salt of benzenesulfonate.

The second type of chemical additives which are inorganic salts of aluminate;

include but are not limited to sodium, or potassium or ammonium salt of aluminate.

The silica particles include, but are not limited to, fumed silica, colloidal silica, high purity colloidal silica, or any other silica particles with different sizes and shapes.

The particle sizes of these fumed silica, colloidal silica, high purity colloidal silica, or any other silica particles in the disclosed invention herein are ranged from 10nm to 1,000nm, the preferred mean particle sized are ranged from 20nm to 500nm, the more preferred mean particle sizes are ranged from 50nm to 250nm.

The concentrations of these fumed silica, colloidal silica, high purity colloidal silica, or any other silica particles range from 0.01 wt. % to 20 wt. %, the preferred concentrations range from 0.05 wt. % to 10 wt. %, the more preferred concentrations range from 0.1 wt. % to 7.5 wt. %.

The preferred abrasives are the high purity colloidal silica particles with different shapes and sizes.

The water soluble solvent includes but is not limited to deionized (DI) water, distilled water, and alcoholic organic solvents.

The preferred water soluble solvent is DI water.

The low-k or ultra-low-k CMP polishing composition may contain biocide from 0.0001 wt. % to 0.05 wt. %; preferably from 0.0005 wt. % to 0.025 wt. %, and more preferably from 0.001 wt. % to 0.01 wt. %.

The biocide includes, but is not limited to, Kathon™, Kathon™ CG/ICP II, from Dupont/Dow Chemical Co. Bioban from Dupont/Dow Chemical Co. They have active ingredients of 5-chloro-2-methyl-4-isothiazolin-3-one and 2-methyl-4-isothiazolin-3-one.

The low-k or ultra-low-k CMP polishing composition may contain a pH adjusting agent.

An acidic or basic pH adjusting agent can be used to adjust the low-k or ultra-low-k CMP polishing compositions to the optimized pH value.

The pH adjusting agents include, but are not limited to nitric acid, hydrochloric acid, sulfuric acid, phosphoric acid, other inorganic or organic acids, and mixtures thereof.

pH adjusting agents also include the basic pH adjusting agents, such as sodium hydride, potassium hydroxide, ammonium hydroxide, tetraalkyl ammonium hydroxide, organic quaternary ammonium hydroxide compounds, organic amines, and other chemical reagents that can be used to adjust pH towards the more alkaline direction.

The low-k or ultra-low-k CMP polishing composition contains 0 wt. % to 2.0 wt. %; preferably 0.01 wt. % to 1.5 wt. %; more preferably 0.1 wt. % to 1.0 wt. % pH adjusting agent.

In another aspect, there is provided a method of chemical mechanical polishing (CMP) a substrate having at least one surface comprising low-k or ultra-low-k film using the chemical mechanical polishing (CMP) composition described above in low-k film CMP polishing process.

In another aspect, there is provided a system of chemical mechanical polishing (CMP) a substrate having at least one surface comprising low-k or ultra-low-k film using the chemical mechanical polishing (CMP) composition described above low-k film CMP polishing process.

The polished low-k or ultra-low-k films included, but not limited to, fluorine doped silicon oxide, carbon-doped oxide, porous silicon oxide, spin-on organic polymeric dielectrics, and spin-on silicon based polymeric dielectric film, etc.

The polished oxide films can be Chemical vapor deposition (CVD), Plasma Enhance CVD (PECVD), High Density Deposition CVD(HDP), or spin on oxide films.

The polished nitride films can be Chemical vapor deposition (CVD) SiN, Plasma

Enhance CVD (PECVD) SiN, or LPCVD SiN film.

The following non-limiting examples are presented to further illustrate the present invention.

### CMP Methodology

In the examples presented below, CMP experiments were run using the procedures and experimental conditions given below.

### Glossary

### Components

High purity colloidal silica: used as abrasive having a particle size of approximately 70 nanometers (nm); such high purity colloidal silica particles (made from TEOS or TMOS through catalytic hydrolysis reaction processes) can have a particle size of ranged from approximately 20 nanometers (nm) to 500 nanometers (nm) with spherical, cocoon or aggregate shapes.

High purity colloidal silica particles (with varied sizes) were supplied by Fuso Chemical Inc. in Japan.

Both first type and second type of chemical additives, such as benzenesulfonate salt or aluminate salt were supplied by Sigma-Aldrich, St. Louis, MO.

TEOS: tetraethyl orthosilicate

Polishing Pad: Polishing pad, IC1010 and other pads were used during CMP, supplied by DOW, Inc.

### Parameters

### General

Åαor A: angstrom(s)—a unit of length

BP: back pressure, in psi units

CMP: chemical mechanical planarization=chemical mechanical polishing

CS: carrier speed

DF: Down force: pressure applied during CMP, units psi

min: minute(s)

ml: milliliter(s)

mV: millivolt(s)

psi: pounds per square inch

PS: platen rotational speed of polishing tool, in rpm (revolution(s) per minute)

SF: composition flow, ml/min

Wt. %: weight percentage (of a listed component)

Low-k or ultra-low-k: SiN Selectivity: (removal rate of low-k or ultra-low-k)/(removal rate of SiN)

Low-k or ultra-low-k: Oxide Selectivity: (removal rate of low-k or ultra-low-k)/(removal rate of TEOS)

Film Removal Rates: Measured film removal rate at a given down pressure. The down pressure of the CMP tool was 2.0 psi in the examples listed below.

### Metrology

Films were measured with a ResMap CDE, model 168, manufactured by Creative Design Engineering, Inc, 20565 Alves Dr., Cupertino, Calif., 95014. The ResMap tool is a four-point probe sheet resistance tool. Forty-nine-point diameter scan at 5mm edge exclusion for film was taken.

### CMP Tool

The CMP tool that was used is a 200mm Mirra, or 300mm Reflexion manufactured by Applied Materials, 3050 Boweres Avenue, Santa Clara, California, 95054. An IC1010 pad supplied by DOW, Inc, 451 Bellevue Rd., Newark, DE 19713 was used on platen 1 for blanket and pattern wafer studies.

The IC1010 pad or other pad was broken in by conditioning the pad for 18 mins. At 7 lbs. down force on the conditioner. To qualify the tool settings and the pad break-in two tungsten monitors and two TEOS monitors were polished with Versum® STI2305 composition, supplied by Versum Materials Inc. at baseline conditions.

### Wafers

Polishing experiments were conducted using low-k or ultra-low-k, such as LK2.5 (the ultra-low-k film with k-constant at 2.5); PECVD SiN. PECVD or LECVD TEOS wafers. These blanket wafers were purchased from Silicon Valley Microelectronics, 2985 Kifer Rd., Santa Clara, Calif. 95051 or were provided by Versum Materials Inc.

Polishing Experiments

In blanket wafer studies, low-k or ultra-low-k blanket wafers, oxide blanket wafers, and SiN blanket wafers were polished at baseline conditions. The tool baseline conditions were: table speed; 90 rpm, head speed: 84 rpm, membrane pressure; 2.0 psi, composition flow; 200 ml/min. The polishing pad used for testing was IC1010 pad which was supplied by Dow Chemicals.

Working Examples

In the following working examples, a basic low-k film polishing composition comprising high purity colloidal silica (HPCS) particles with cocoon shape and mean particle size of 68nm at 1X concentration (3.1035 wt. %), benzene sulfonate (BSA) at 1× concentration (0.4601 wt. %), sodium salt of aluminate at 1× concentration (=0.25 wt. %), an acetylene ethoxylate type of surfactant Dyno1607 at 1× concentration (0.00775 wt. %), and potassium hydroxide as pH adjusting agent as needed wt. % to adjust the pH or the working samples to the targeted pH values, and deionized water

A corrosion inhibitor could also be added in the polishing compositions, for example, benzotriazole (BTA) was used at 1× concentration (0.01052 wt. %).

### EXAMPLE 1

In Example 1, the polishing compositions used for low-k or ultra-low-k film polishing, LK2.5, TEOS film and SiN film. The pH of the compositions ranged from 11.75 to 12.60.

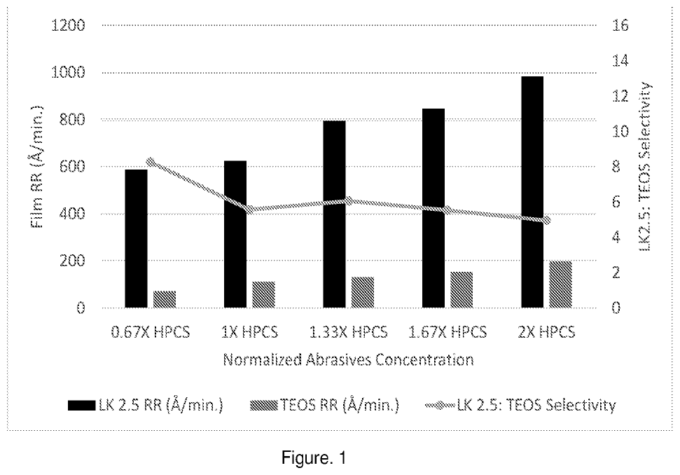

The results of removal rates, and selectivity of LK film: TEOS were shown in Table 1 and depicted in FIG. 1.

The polishing step conditions used are: Dow's IC1010 pad at 2.0 psi DF with table/head speed at 90/84 rpm and in-situ conditioning.

TABLE 1
LK2.5 and TEOS Film RR (Å/min.) & LK2.5 Film: TEOS Selectivity

| | LK 2.5 RR | TEOS RR | LK 2.5: TEOS |
|---|---|---|---|
| Compositions | (Å/min.) | (Å/min.) | Selectivity |
| 1 × BSA/1 × Aluminate/1 × | 588 | 71 | 8.28:1 |
| Dynol 607/0.67 × HPCS | | | |
| 1 × BSA/1 × Aluminate/1 × | 625 | 112 | 5.58:1 |
| Dynol 607/1 × HPCS | | | |
| 1 × BSA/1 × Aluminate/1 × | 795 | 131 | 6.07:1 |
| Dynol 607/1.33 × HPCS | | | |
| 1 × BSA/1 × Aluminate/1 × | 848 | 153 | 5.54:1 |
| Dynol 607/1.67 × HPCS | | | |
| 1 × BSA/1 × Aluminate/1 × | 984 | 198 | 4.97:1 |
| Dynol 607/2 × HPCS | | | |

As the results shown in Table 1 and FIG. 1, The increased abrasive concentrations also led to the gradually increased ultra-low-k film removal rates. The higher LK2.5 film: TEOS selectivity at 8.3:1 was achieved with 0.67× concentrated high purity colloidal silica abrasives.

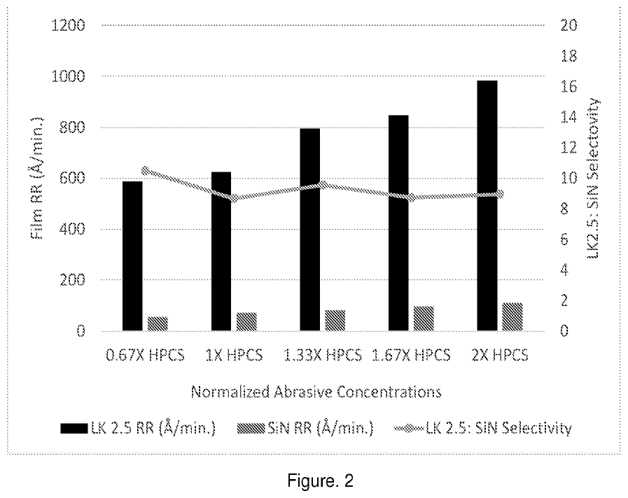

The results of removal rates, and selectivity of LK2.5 and SiN film were shown in Table 2 and depicted in FIG. 2.

TABLE 2
LK2.5 and SiN Film RR (Å/min.) & LK2.5 Film: Sin Selectivity

| | LK 2.5 RR | SiN RR | LK 2.5: TEOS |
|---|---|---|---|
| Compositions | (Å/min.) | (Å/min.) | Selectivity |
| 1 × BSA/1 × Aluminate/1 × | 588 | 56 | 10.5:1 |
| Dynol 607/0.67 × HPCS | | | |
| 1 × BSA/1 × Aluminate/1 × | 625 | 72 | 8.68:1 |
| Dynol 607/1 × HPCS | | | |
| 1 × BSA/1 × Aluminate/1 × | 795 | 83 | 9.56:1 |
| Dynol 607/1.33 × HPCS | | | |
| 1 × BSA/1 × Aluminate/1 × | 848 | 97 | 8.74:1 |
| Dynol 607/1.67 × HPCS | | | |
| 1 × BSA/1 × Aluminate/1 × | 984 | 110 | 8.95:1 |
| Dynol 607/2 × HPCS | | | |

As the results shown in Table 2 and FIG. 2, the increased abrasive concentrations also led to the gradually increased ultra-low-k film removal rates. The higher LK2.5 film: SiN selectivity at 10.5:1 was achieved with 0.67× concentrated high purity colloidal silica abrasives.

When 1× benzotriazole (BTA) was optionally used as a corrosion inhibitor in the basic low-k film polishing composition, the low-k film removal rates was 706 Å/min.; the oxide film removal rate was 109 Å/min.; and the SiN film removal rate was 71 Å/min.

### EXAMPLE 2

In Example 2, the basic low-k film polishing composition with different pH were used for polishing LK2.5 film, TEOS film, SiN film at different pH.

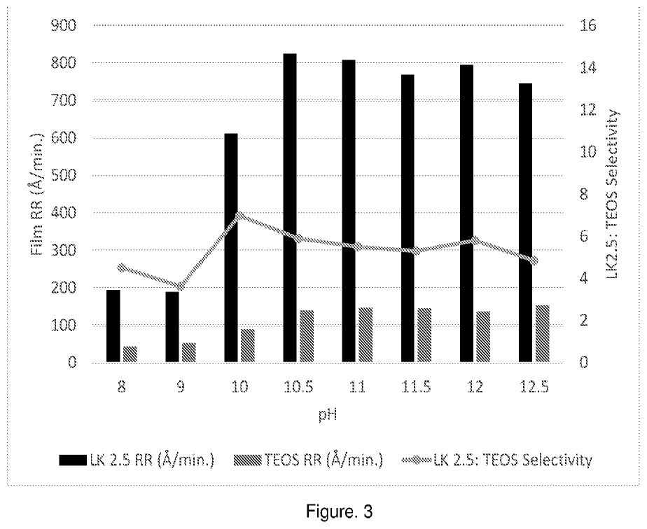

The results of LK2.5 film and TEOS film removal rates and LK2.5 film: TEOS selectivity were also listed in Table 3 and depicted in FIG. 3.

TABLE 3
Effects of pH on LK2.5 & TEOS RR(A/min.)
& Selectivity of LK2.5: TEOS

| 1 × BSA/1 × | | | |
|---|---|---|---|
| Aluminate/1 × | LK 2.5 RR | TEOS RR | LK 2.5: TEOS |
| Dynol 607/1 × HPCS | (Å/min.) | (Å/min.) | Selectivity |
| pH 8.0 | 194 | 43 | 4.51 |
| pH 9.0 | 189 | 52 | 3.63 |
| pH 10.0 | 612 | 89 | 6.98 |
| pH 10.5 | 825 | 140 | 5.89 |
| pH 11.0 | 808 | 147 | 5.5 |
| pH 11.5 | 769 | 145 | 5.3 |
| pH 12.0 | 795 | 137 | 5.8 |
| pH 12.5 | 745 | 154 | 4.84 |

As the results shown in Table 3 and FIG. 3, the invented herein low-k CMP polishing composition gave higher ultra-low-k film removal rates when it was used in the pH range of 8.0 to 12.5, preferably at 10.0 to 12.5.

The polishing composition also provided higher low-k film: oxide selectivity in the pH range of 8.0 to 12.5, preferably at 10.0 to 12.0.

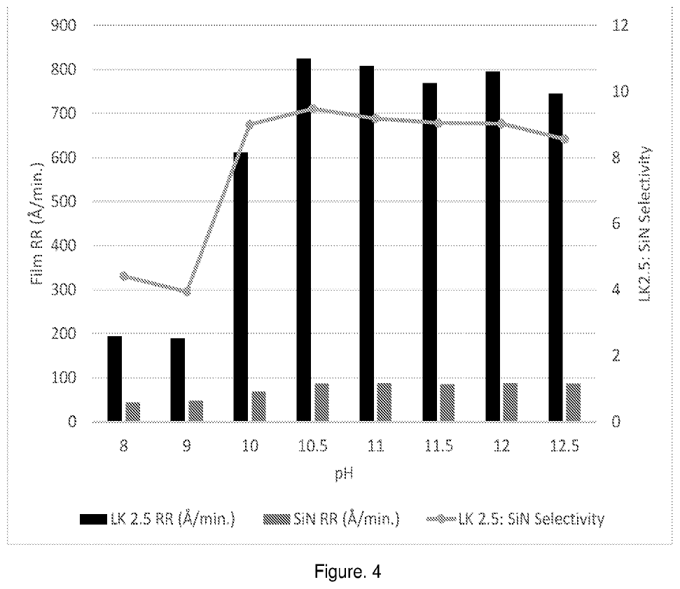

The results of LK2.5 film and SiN film removal rates; and LK2.5 film: Sin selectivity were also listed in Table 4 and depicted in FIG. 4.

As the results shown in Table 4 and FIG. 4, the invented herein low-k CMP polishing composition gave higher ultra-low-k film removal rates when it was used in the pH range of 8.0 to 12.5, preferably at 10.0 to 12.5.

TABLE 4
Effects of pH on LK2.5 and SiN RR(A/min.) & Selectivity of LK2.5: SiN

| 1 × BSA/1 × | | | |
|---|---|---|---|
| Aluminate/1 × | LK 2.5 RR | SiN RR | LK 2.5: TEOS |
| Dynol 607/1 × HPCS | (Å/min.) | (Å/min.) | Selectivity |
| pH 8.0 | 194 | 44 | 4.41 |
| pH 9.0 | 189 | 48 | 3.94 |
| pH 10.0 | 612 | 68 | 9 |
| pH 10.5 | 825 | 87 | 9.48 |
| pH 11.0 | 808 | 88 | 9.18 |
| pH 11.5 | 769 | 85 | 9.05 |
| pH 12.0 | 795 | 88 | 9.03 |
| pH 12.5 | 745 | 87 | 8.56 |

The polishing composition also provided higher low-k film: SiN selectivity in the pH range of 8.0 to 12.5, preferably at 10.0 to 12.5.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical mechanical polishing composition comprising:
abrasive selected from the group consisting of inorganic oxide particles, coated inorganic oxide particles; and combinations thereof;
inorganic salt of aluminate;
a chemical additive selected from the group consisting of:
(a) 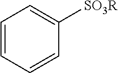
where —R can be hydrogen atom, metal ion, or ammonium ion; 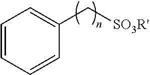
(b)
where —R′ can be hydrogen atom, a metal ion, or ammonium ion; n is from 1 to 12 for length of alkyl linkage group -CH2-; and the metal ion is sodium ion, or potassium ion;
and
(c) combinations thereof;
a water-soluble solvent selected from the group consisting of deionized (DI) water, distilled water, and alcoholic organic solvents; and
optionally
corrosion inhibitor;
surfactant; and
pH adjuster;
wherein
the inorganic oxide particles are selected from the group comprising of calcined ceria, colloidal silica, high purity colloidal silica, alumina, titania, zirconia particles, and combinations thereof; and
the metal-coated inorganic oxide particles are ceria-coated inorganic oxide particles selected from the group comprising of ceria-coated colloidal silica, ceria-coated high purity colloidal silica, ceria-coated alumina, ceria-coated titania, ceria-coated zirconia, and combinations thereof; and
the composition has a pH of 4 to 13.

2. (canceled)

3. The chemical mechanical polishing composition of claim 1, wherein the abrasive is selected from the group comprising of fumed silica particles, colloidal silica particles or high purity colloidal silica particles, and combinations thereof; and size of the particles ranges from 5nm to 1,000nm, preferably from 35nm to 100nm; and shape of the particles is selected from the group comprising of spherical, cocoon, aggregate, and combinations thereof.

4. The chemical mechanical polishing composition of claim 1, wherein the inorganic salts of aluminate is selected from the group comprising of sodium salt, potassium salt, ammonium salt, and combinations thereof.

5. The chemical mechanical polishing composition of claim 1, wherein —R in (a) is selected from the group consisting of (i) hydrogen atom, and the chemical additive is benzenesulfonic acid; and (ii)sodium ion, potassium ion, or ammonium ion;
and the chemical additive is a salt of benzenesulfonate.

6. (canceled)

7. (canceled)

8. The chemical mechanical polishing composition of claim 1, wherein
(a) the composition further comprises at least one selected from the group consisting of biocide having active ingredients of 5-chloro-2-methyl-4-isothiazolin-3-one and 2-methyl-isothiazolin-3-one;
(b) a pH adjusting agent selected from the group comprising of nitric acid, hydrochloric acid, sulfuric acid, phosphoric acid, and combinations thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions;
(c) a corrosion inhibitor; and
(d) a surfactant selected from non-ionic, anionic, or cationic types of surfactants.

9. (canceled)

10. (canceled)

11. A method of chemical mechanical polishing (CMP) a semiconductor substrate having at least one surface comprising low-k or ultra-low-k film, comprising providing the semiconductor substrate;
providing a polishing pad;
providing the chemical mechanical polishing (CMP) composition of claim 1;
contacting the surface of the semiconductor substrate with the polishing pad and the chemical mechanical polishing composition; and
polishing the least one surface comprising low-k or ultra-low-k film;
wherein the substrate optionally has at least one surface comprising silicon oxide film, silicon nitride film, or combinations thereof.

12. The method of claim 11; wherein the low-k or ultra-low-k film is selected from the group comprising fluorine doped silicon oxide, carbon-doped oxide, porous silicon oxide, spin-on organic polymeric dielectrics, spin-on silicon based polymeric dielectric film, and combinations thereof.

13. (canceled)

14. The method of claim 11; wherein the silicon oxide film is selected from the group comprising Chemical vapor deposition (CVD), Plasma Enhance CVD (PECVD), High Density Deposition CVD(HDP), spin on oxide films, and combinations thereof; and the silicon nitride films is selected from the group comprising Chemical vapor deposition (CVD) SiN, Plasma Enhance CVD (PECVD) SiN, LPCVD SiN film, and combinations thereof.

15. The method of claim 11; wherein removal selectivity of Low-k to silicon oxide film is ≥4:1.

16. The method of claim 12; wherein removal selectivity of Low-k to silicon nitride film is ≥7:1.

17. A system of chemical mechanical polishing (CMP) a semiconductor substrate having at least one surface comprising low-k or ultra-low-k film, and optionally at least one surface comprising silicon oxide film, silicon nitride film, or combinations thereof, comprising
a. the semiconductor substrate;
b. the chemical mechanical polishing (CMP) composition of claim 1;
c. a polishing pad;
wherein the at least one surface comprising low-k or ultra-low-k film and the optionally at least one surface comprising silicon oxide film, silicon nitride film, or combinations thereof are in contact with the polishing pad and the chemical mechanical polishing composition.

18. The chemical mechanical polishing composition of claim 1, wherein the composition comprises colloidal silica particles; benzenesulfonic acid, sodium salt of aluminate, deionized water, and the composition has a pH of 8 to 13.

19. The chemical mechanical polishing composition of claim 1, wherein the composition comprises colloidal silica particles; benzenesulfonic acid, sodium salt of aluminate, deionized water, at least one selected from the group consisting of an acetylene ethoxylate type of surfactant, and potassium hydroxide, benzotriazole, and the composition has a pH of 8 to 13.
